(19) United States
(12) Patent Application Publication
(10) Pub. No.: US 2024/0175921 A1
(43) Pub. Date: May 30, 2024

(54) CHIP WITH CLOCK MASKING CIRCUIT

(71) Applicant: REALTEK SEMICONDUCTOR CORP., Hsinchu (TW)

(72) Inventor: Po-Lin Chen, Hsinchu (TW)

(73) Assignee: REALTEK SEMICONDUCTOR CORP., Hsinchu (TW)

(21) Appl. No.: 18/522,489

(22) Filed: Nov. 29, 2023

(30) Foreign Application Priority Data
Nov. 30, 2022 (TW) 111146042

(51) Int. Cl. G01R 31/317

(52) U.S. Cl. CPC G01R 31/31725

(57) ABSTRACT

A chip includes a first circuit under test, a second circuit under test, and a clock masking circuit. The first circuit under test is coupled to the second circuit under test. The clock masking circuit includes a first clock control circuit, a second clock control circuit, and an enabling circuit. The first clock control circuit is configured to provide a first clock signal for the first circuit under test according to a first enable signal and an initial clock signal. The second clock control circuit is configured to provide a second clock signal for the second circuit under test according to a second enable signal and the initial clock signal. The enabling circuit is configured to provide a first enable signal for the first clock control circuit and a second enable signal for the second clock control circuit.

### CROSS-REFERENCE TO RELATED APPLICATION

This non-provisional application claims priority under 35 U.S.C. § 119(a) to Patent Application No. 111146042 filed in Taiwan, R.O.C. on Nov. 30, 2022, the entire contents of which are hereby incorporated by reference.

### BACKGROUND

### Technical Field

The instant disclosure is related to circuit testing, especially a chip having a clock masking circuit which has the functions of reducing area costs of the circuits under test and increasing test coverage.

### Related Art

In transition delay fault (TDF) tests known to the inventor, on-chip clock controllers (OCCs) are used to apply full-speed clock pulses to test whether the devices under test (DUTs) are able to operate at their target operation frequencies. However, some circuits internal to the DUTs may operate at slower clock frequencies, or the clock frequencies of some circuits internal to the DUTs may be preconfigured and be constant values during the operation of the DUTs. For these circuits, timing constraint is usually used to avoid circuit synthesis tools or automatic placement and routing (APR) tools spending too much effort on these circuits.

However, circuits constrained by timing cannot timely generate correct outputs; instead, these circuits will generate unknown signals. These unknown signals will affect test results. The level of effect of the unknown signals is proportional to the number of time constraints or the range of time constraint coverage. Conventionally, commercial tools mask the effect of unknown signals by locating all terminals of the scan flip-flops affected by the unknown signals and adding gating circuits at the terminals of each affected scan flip-flop.

However, adding the gating circuits to mask the effect of the unknown signals leads to additional area costs of the DUTs, and the gating circuits may also mask test responses transmitted by the DUTs through the actual functional paths and thus further cause the test coverage to decrease.

### SUMMARY

In an embodiment, a chip comprises a first circuit under test, a second circuit under test, and a clock masking circuit. The second circuit under test is coupled to the first circuit under test. The clock masking circuit comprises a first clock control circuit, a second clock control circuit, and an enabling circuit. The first clock control circuit is configured to provide a first clock signal for the first circuit under test according to a first enable signal and an initial clock signal. The second clock control circuit is configured to provide a second clock signal for the second circuit under test according to a second enable signal and the initial clock signal. The enabling circuit is configured to provide the first enable signal for the first clock control circuit and provide the second enable signal for the second clock control circuit. During a first operation period, the first enable signal enables the first clock control circuit to provide the first clock signal for the first circuit under test, and the second enable signal disables the second clock control circuit from providing the second clock signal for the second circuit under test. During a second operation period, the first enable signal disables the first clock control circuit from providing the first clock signal for the first circuit under test, and the second enable signal enables the second clock control circuit to provide the second clock signal for the second circuit under test. The first operation period does not overlap with the second operation period.

In an embodiment, a chip comprises a first circuit under test, a second circuit under test, and a clock masking circuit. The second circuit under test is coupled to the first circuit under test. The clock masking circuit comprises a first clock control circuit, a second clock control circuit, and an enabling circuit. The first clock control circuit is configured to provide a first clock signal for the first circuit under test according to a first enable signal and an initial clock signal. The second clock control circuit is configured to provide a second clock signal for the second circuit under test according to a second enable signal and the initial clock signal. The enabling circuit is configured to provide the first enable signal for the first clock control circuit and provide the second enable signal for the second clock control circuit. During a first operation period, the first enable signal enables the first clock control circuit to provide the first clock signal for the first circuit under test, and the second enable signal disables the second clock control circuit from providing the second clock signal for the second circuit under test. During a second operation period, the first enable signal disables the first clock control circuit from providing the first clock signal for the first circuit under test, and the second enable signal enables the second clock control circuit to provide the second clock signal for the second circuit under test. During a third operation period, the first enable signal enables the first clock control circuit to provide the first clock signal for the first circuit under test, and the second enable signal enables the second clock control circuit to provide the second clock signal for the second circuit under test. The first operation period, the second operation period, and the third operation period do not overlap with each other.

In an embodiment, a chip comprises a first circuit under test, a second circuit under test, a clock source circuit, and a clock masking circuit. The second circuit under test is coupled to an input end of the first circuit under test. The clock source circuit is configured to provide an initial clock signal. The clock masking circuit comprises a first clock control circuit and an enabling circuit. The first clock control circuit is configured to provide a first clock signal for the first circuit under test according to a first enable signal and the initial clock signal. The enabling circuit is configured to provide the first enable signal for the first clock control circuit. During a first operation period, the first enable signal enables the first clock control circuit to provide the first clock signal for the first circuit under test, and the clock source circuit provides the initial clock signal for the second circuit under test. During a second operation period, the first enable signal disables the first clock control circuit from providing the first clock signal for the first circuit under test, and the clock source circuit provides the initial clock signal for the second circuit under test. The first operation period does not overlap with the second operation period.

In an embodiment, a chip comprises a first circuit under test, a third circuit under test, a clock source circuit, and a clock masking circuit. The third circuit under test is coupled to an output end of the first circuit under test. The clock source circuit is configured to provide an initial clock signal. The clock masking circuit comprises a first clock control circuit and an enabling circuit. The first clock control circuit is configured to provide a first clock signal for the first circuit under test according to a first enable signal and the initial clock signal. The enabling circuit is configured to provide the first enable signal for the first clock control circuit. During a first operation period, the first enable signal enables the first clock control circuit to provide the first clock signal for the first circuit under test, and the clock source circuit provides the initial clock signal for the third circuit under test. During a second operation period, the first enable signal disables the first clock control circuit from providing the first clock signal for the first circuit under test, and the clock source circuit provides the initial clock signal for the third circuit under test. The first operation period does not overlap with the second operation period.

The following will describe the detailed features and advantages of the instant disclosure in detail in the detailed description. The content of the description is sufficient for any person skilled in the art to comprehend the technical context of the instant disclosure and to implement it accordingly. According to the content, claims and drawings disclosed in the instant specification, any person skilled in the art can readily understand the goals and advantages of the instant disclosure.

### BRIEF DESCRIPTION OF THE DRAWINGS

The instant disclosure will become more fully understood from the detailed

description given herein below for illustration only, and thus not limitative of the instant disclosure, wherein:

FIG. 1 illustrates a schematic block diagram of an embodiment of a chip;

FIG. 2 illustrates schematic waveforms of an embodiment of a first clock signal and a second clock signal;

FIG. 3 illustrates a schematic circuit diagram of an embodiment of a clock masking circuit;

FIG. 4 illustrates schematic waveforms of an embodiment of signals related to the clock masking circuit during two shift phases and a first operation period;

FIG. 5 illustrates schematic waveforms of an embodiment of the signals related to the clock masking circuit during two shift phases and a second operation period;

FIG. 6 illustrates a schematic block diagram of another embodiment of the chip;

FIG. 7 illustrates schematic waveforms of another embodiment of the first clock signal and the second clock signal;

FIG. 8 illustrates a schematic circuit diagram of another embodiment of the clock masking circuit;

FIG. 9 illustrates a schematic block diagram of yet another embodiment of the chip;

FIG. 10 illustrates schematic waveforms of yet another embodiment of the initial clock signal and the first clock signal; and

FIG. 11 illustrates a schematic block diagram of a further embodiment of the chip.

### DETAILED DESCRIPTION

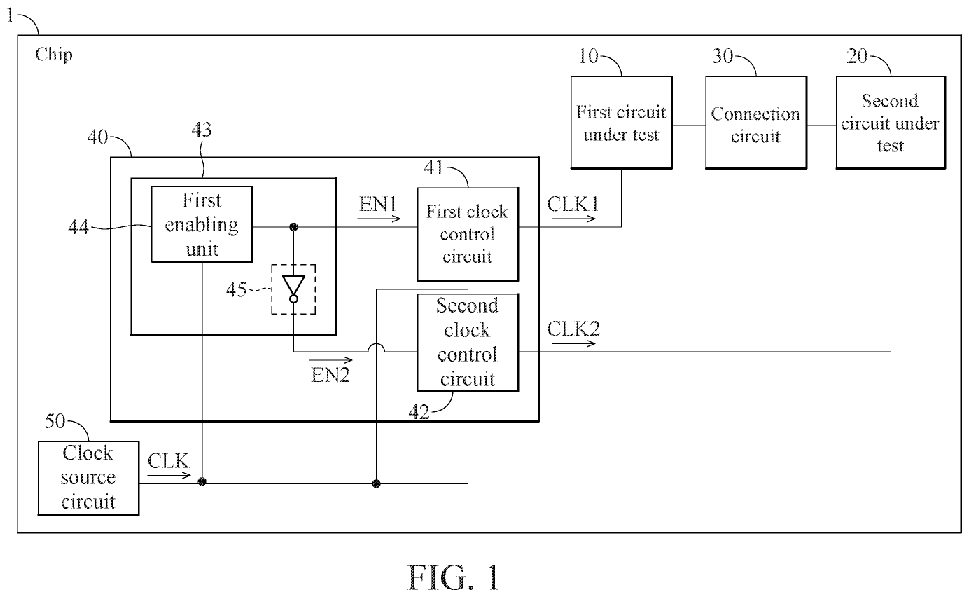

FIG. 1 illustrates a schematic block diagram of an embodiment of a chip 1. Please refer to FIG. 1. The chip 1 comprises a first circuit under test 10, a second circuit under test 20, a connection circuit 30, a clock masking circuit 40, and a clock source circuit 50. The first circuit under test 10 is coupled to the second circuit under test 20. The clock masking circuit 40 is coupled to the first circuit under test 10, the second circuit under test 20, and the clock source circuit 50. In different embodiments, that the first circuit under test 10 is coupled to the second circuit under test 20 may be that the first circuit under test 10 is directly or indirectly connected to the second circuit under test 20. In embodiments adopting indirect connection, the first circuit under test 10 may be indirectly connected to the second circuit under test 20 through the connection circuit 30.

The first circuit under test 10 and the second circuit under test 20 are circuits that are under test in a transition delay fault (TDF) test. In some embodiments, a time domain of the first circuit under test 10 and a time domain of the second circuit under test 20 are different time domains, and the first circuit under test 10 and the second circuit under test 20 may be, but not limited to, implemented using one or more scan flip-flops.

In some embodiments, the TDF test for the chip 1 includes a shift phase and a capture phase. During the shift phase, the scan flip-flop internal to the first circuit under test 10 and the scan flip-flop internal to the second circuit under test 20 receive test patterns by scanning input signals and slowly shifting clocks. During the capture phase, the first circuit under test 10 and the second circuit under test 20 obtain test responses according to the test patterns received during the shift phase and compare the test responses with a default correct value to obtain test results. In some embodiments, the TDF test for the chip 1 changes between the shift phase and the capture phase according to a scan enable signal.

In some embodiments, the connection circuit 30 may be implemented using one or more hardware modules. In different embodiments, the hardware modules may be logic gates, adders, multipliers, latches, registers, or flip-flops, and the types of hardware modules are not limited in the instant disclosure.

In some embodiments, a timing constraint causes a data path from the first circuit under test 10 to the second circuit under test 20 and the data path from the second circuit under test 20 to the first circuit under test 10 to both be false paths or multicycle paths. In some embodiments, commands for the timing constraint may be, but not limited to, set_false_path, set_clock_group, or set_multicycl_path.

The clock masking circuit 40 comprises a first clock control circuit 41, a second clock control circuit 42, and an enabling circuit 43. The first clock control circuit 41 is configured to provide a first clock signal CLK1 for the first circuit under test 10 according to a first enable signal EN1 and an initial clock signal CLK. The second clock control circuit 42 is configured to provide a second clock signal CLK2 for the second circuit under test 20 according to a second enable signal EN2 and the initial clock signal CLK. The enabling circuit 43 is configured to provide the first enable signal EN1 for the first clock control circuit 41 and provide the second enable signal EN2 for the second clock control circuit 42. In some embodiments, the enabling circuit 43 comprises a first enabling unit 44 and an inverter 45. The first enabling unit 44 is configured to provide the first enable signal ENI for the first clock control circuit 41. The inverter 45 is configured to invert the first enable signal EN1 so as to provide the second enable signal EN2 for the second clock control circuit 42. In some embodiments, the inverter 45 may be, but not limited to, a PMOS inverter, an NMOS inverter, or a CMOS inverter.

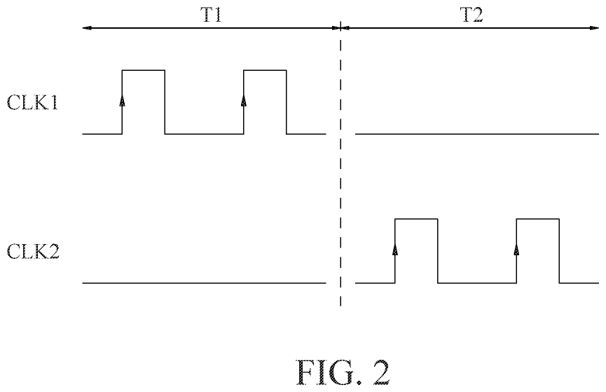

FIG. 2 illustrates schematic waveforms of an embodiment of the first clock signal CLK1 and the second clock signal CLK2. Please refer to FIG. 1 and FIG. 2. During a first operation period T1, the first enable signal EN1 enables the first clock control circuit 41 to provide the first clock signal CLK1 for the first circuit under test 10, and the second enable signal EN2 disables the second clock control circuit 42 from providing the second clock signal CLK2 for the second circuit under test 20. During a second operation period T2, the first enable signal EN1 disables the first clock control circuit 41 from providing the first clock signal CLK1 for the first circuit under test 10, and the second enable signal EN2 enables the second clock control circuit 42 to provide the second clock signal CLK2 for the second circuit under test 20. The first operation period T1 does not overlap with the second operation period T2. In some embodiments, the first operation period T1 and the second operation period T2 are the capture phases of the TDF test for the chip 1.

As a result, during the first operation period T1, because the second clock signal CLK2 is inhibited, data of the second circuit under test 20 will not be captured by the first circuit under test 10, and the scan flip-flop which is internal to the first circuit under test 10 and uses the time domain of the first clock signal CLK1 can still capture the test responses. On the contrary, during the second operation period T2, because the first clock signal CLK1 is inhibited, data of the first circuit under test 10 will not be captured by the second circuit under test 20, and the scan flip-flop which is internal to the second circuit under test 20 and uses the time domain of the second clock signal CLK2 can still capture the test responses. As a result, the clock masking circuit 40 allows the chip 1 to only activate one time domain during a single capture phase to prevent the second circuit under test 20 from capturing the data of the first circuit under test 10 from the first circuit under test 10 or prevent the first circuit under test 10 from capturing the data of the second circuit under test 20 from the second circuit under test 20. Therefore, the propagation of the unknown signals of the first circuit under test 10 and the second circuit under test 20 can be thus avoided without affecting the abilities of the first circuit under test 10 and the second circuit under test 20 to capture the test responses, so that the test coverage of the chip 1 is increased. As a result, design for gating circuits for masking unknown signals is not necessarily required, and the area cost internal to the chip 1 is reduced.

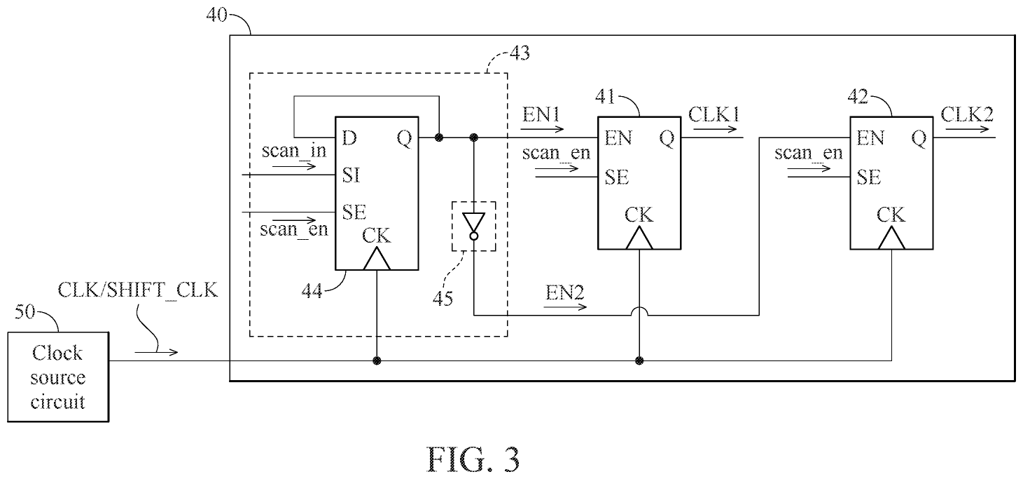

FIG. 3 illustrates a schematic circuit diagram of an embodiment of the clock masking circuit 40. Please refer to FIG. 1 through FIG. 3. In some embodiments, the first enabling unit 44 is a scan flip-flop. The first enabling unit 44 comprises an input end D, an output end Q, a clock end CK, a scan input end SI, and a scan enabling end SE. The input end D is coupled to the output end Q. The output end Q is configured to provide the first enable signal EN1 for the first clock control circuit 41. The clock end CK is configured to receive the initial clock signal CLK and a shift clock signal SHIFT_CLK provided by the clock source circuit 50. In some embodiments, a frequency of the initial clock signal CLK is greater than a frequency of the shift clock signal SHIFT_CLK. The scan input end SI is configured to receive a scan input signal scan_in. The scan flip-flop internal to the first circuit under test 10 and the scan flip-flop internal to the second circuit under test receive the test patterns through the scan input signal scan_in and the shift clock signal SHIFT_CLK during the shift phase. The scan enabling end SE is configured to receive a scan enable signal scan_en. The scan enable signal scan_en is used to change between the shift phase and the capture phase during the TDF test for the chip 1.

In some embodiments, each of the first clock control circuit 41 and the second clock control circuit 42 is a latch. Each of the first clock control circuit 41 and the second clock control circuit 42 comprises an enabling end EN, an output end Q, a scan enabling end SE, and a clock end CK. The enabling end EN of the first clock control circuit 41 is configured to receive the first enable signal EN1 provided by the first enabling circuit 44. The enabling end EN of the second clock control circuit 42 is configured to receive the second enable signal EN2 provided by the inverter 45. The output end Q of the first clock control circuit 41 is configured to provide the first clock signal CLK1 for the first circuit under test 10. The output end Q of the second clock control circuit 42 is configured to provide the second clock signal CLK2 for the second circuit under test 20. The scan enabling end SE of the first clock control circuit 41 and the scan enabling end SE of the second clock control circuit 42 are configured to receive the scan enable signal scan_en. The clock end CK of the first clock control circuit 41 and the clock end CK of the second clock control circuit 42 are configured to receive the initial clock signal CLK and the shift clock signal SHIFT_CLK provided by the clock source circuit 50.

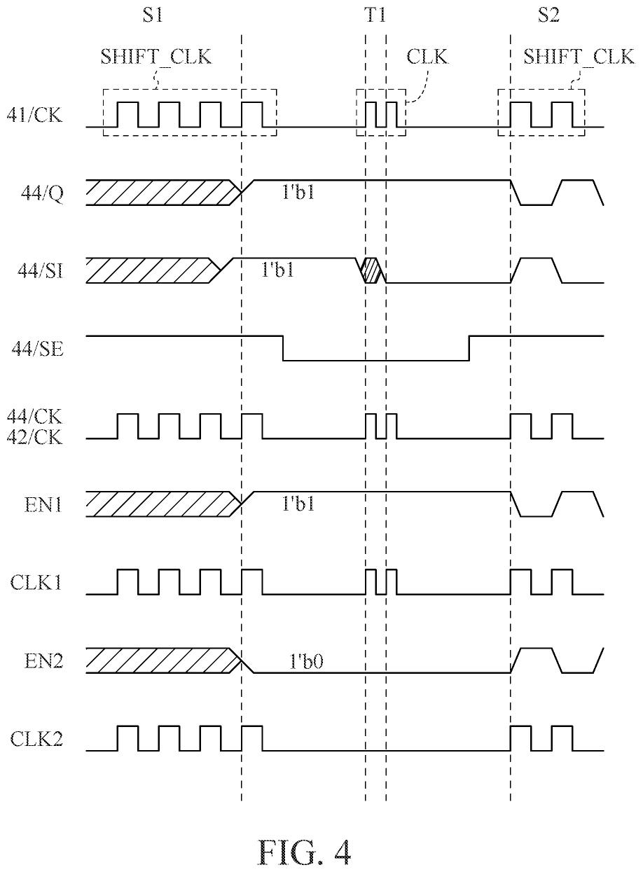

FIG. 4 illustrates schematic waveforms of an embodiment of signals related to the clock masking circuit 40 during the shift phase S1, the shift phase S2, and the first operation period T1. Please refer to FIG. 1 through FIG. 4. In some embodiments, during the shift phase S1 and the shift phase S2, the clock source circuit 50 provides the shift clock signal SHIFT_CLK. In other words, in some embodiments, during the shift phase S1 and the shift phase S2, the clock signal received by the clock end CK of the first enabling unit 44, the clock end CK of the first clock control circuit 41, and the clock end CK of the second clock control circuit 42 is the shift clock signal SHIFT_CLK, while the scan enable signal scan_en is 1 to allow the chip 1 to be in the shift phase of the TDF test. During the first operation period T1, the clock source circuit 50 provides the initial clock signal CLK. In other words, in some embodiments, during the first operation period T1, the clock signal received by the clock end CK of the first enabling unit 44, the clock end CK of the first clock control circuit 41, and the clock end CK of the second clock control circuit 42 is the initial clock signal CLK, while the scan enable signal scan_en is 0 to allow the chip 1 to be in the capture phase of the TDF test.

When the test changes from the shift phase S1 to the first operation period T1, the output end Q of the first enabling unit 44 will be loaded to 1 and will be maintained at 1 throughout the first operation period T1. In other words, in some embodiments, the first enable signal EN1 is maintained at 1 during the first operation period T1. During the first operation period T1, because the enabling end EN of the first clock control circuit 41 receives the first enable signal EN1 which is provided by the first enabling unit 44 and has the signal value of 1, the first clock control circuit 41 takes the initial clock signal CLK received by the clock end CK of the first clock control circuit 41 as the first clock signal CLK1 and provides the first clock signal CLK1 for the first circuit under test 10.

The second enable signal EN2 is a signal obtained by sending the first enable signal EN1 through the inverter 45, and the first enable signal EN1 is maintained at 1 during the first operation period T1. As a result, the second enable signal EN2 is maintained at 0 during the first operation period T1. During the first operation period T1, because the enabling end EN of the second clock control circuit 42 receives the second enable signal EN2 which is provided by the inverter 45 and has the signal value of 0, the second clock control circuit 42 does not take the initial clock signal CLK received by the clock end CK of the second clock control circuit 42 as the second clock signal CLK2 and does not provide the second clock signal CLK2 for the second circuit under test 20. In other words, in some embodiments, the second circuit under test 20 will not receive any clock signal during the first operation period T1.

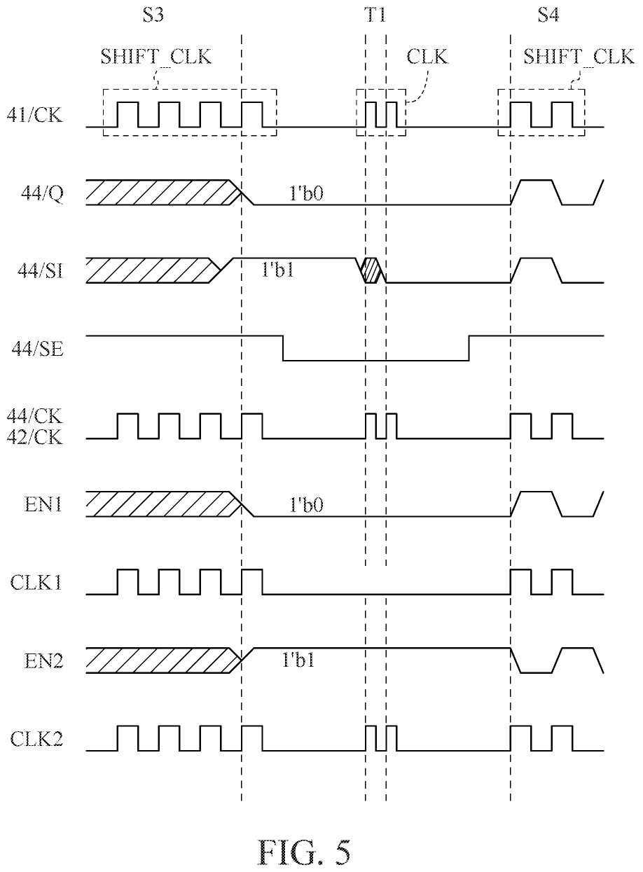

FIG. 5 illustrates schematic waveforms of an embodiment of the signals related to the clock masking circuit 40 during the shift phase S3, the shift phase S4, and the second operation period T2. Please refer to FIG. 1 through FIG. 5. In some embodiments, during the shift phase S3 and the shift phase S4, the clock source circuit 50 provides the shift clock signal SHIFT_CLK. In other words, in some embodiments, during the shift phase S3 and the shift phase S4, the clock signal received by the clock end CK of the first enabling unit 44, the clock end CK of the first clock control circuit 41, and the clock end CK of the second clock control circuit 42 is the shift clock signal SHIFT_CLK, while the scan enable signal scan_en is 1 to allow the chip 1 to be in the shift phase of the TDF test. During the second operation period T2, the clock source circuit 50 provides the initial clock signal CLK. In other words, in some embodiments, during the second operation period T2, the clock signal received by the clock end CK of the first enabling unit 44, the clock end CK of the first clock control circuit 41 and the clock end CK of the second clock control circuit 42 is the initial clock signal CLK, while the scan enable signal scan_en is 0 to allow the chip 1 to be in the capture phase of the TDF test.

When the test changes from the shift phase S3 to the second operation period T2, the output end Q of the first enabling unit 44 will be loaded to 0 and will be maintained at 0 throughout the second operation period T2. In other words, in some embodiments, the first enable signal EN1 is maintained at 0 during the second operation period T2. During the second operation period T2, because the enabling end EN of the first clock control circuit 41 receives the first enable signal EN1 which is provided by the first enabling unit 44 and has the signal value of 0, the first clock control circuit 41 does not take the initial clock signal CLK received by the clock end CK of the first clock control circuit 41 as the first clock signal CLK1 and does not provide the first clock signal CLK1 for the first circuit under test 10. In other words, in some embodiments, the first circuit under test 10 will not receive any clock signal during the second operation period T2.

The second enable signal EN2 is a signal obtained by sending the first enable signal EN1 through the inverter 45, and the first enable signal EN1 is maintained at 0 during the second operation period T2. As a result, the second enable signal EN2 is maintained at 1 during the second operation period T2. During the second operation period T2, because the enabling end EN of the second clock control circuit 42 receives the second enable signal EN2 which is provided by the inverter 45 and has the signal value of 1, the second clock control circuit 42 takes the initial clock signal CLK received by the clock end CK of the second clock control circuit 42 as the second clock signal CLK2 and provides the second clock signal CLK2 for the second circuit under test 20.

The clock source circuit 50 is configured to provide the shift clock signal SHIFT_CLK and the initial clock signal CLK for the clock masking circuit 40. In some embodiments, the clock source circuit 50 may be, but not limited to, an on-chip clock controller (OCC).

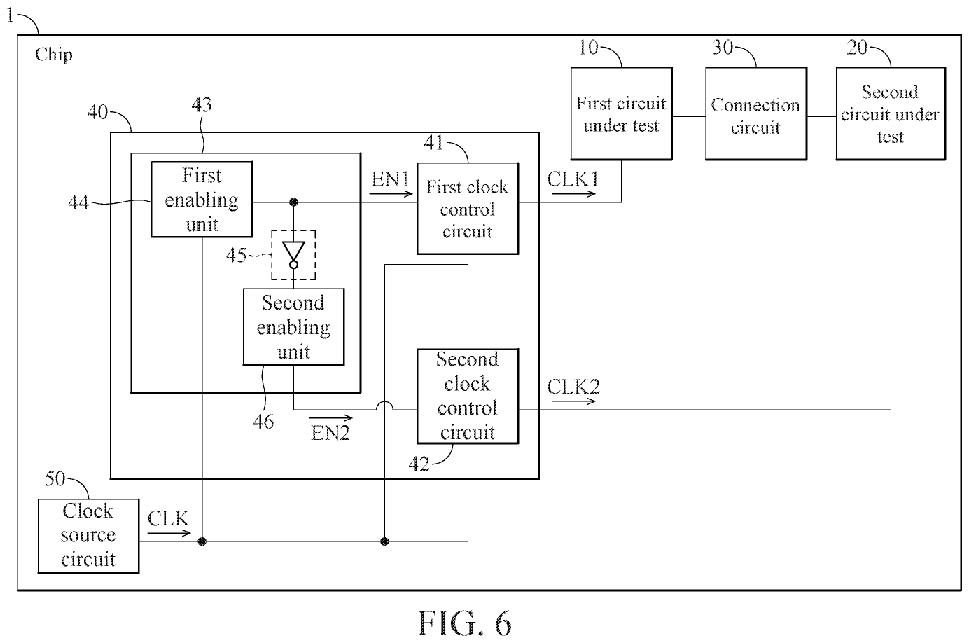

FIG. 6 illustrates a schematic block diagram of another embodiment of the chip 1. Please refer to FIG. 6. In some embodiments, the enabling circuit 43 comprises a first enabling unit 44, an inverter 45, and a second enabling unit 46. The first enabling unit 44 is configured to provide the first enable signal EN1 for the first clock control circuit 41. The inverter 45 is configured to invert the first enable signal EN1 and provide the signal obtained by inverting the first enable signal EN1 for the second enabling unit 46. The second enabling unit 46 is configured to provide the second enable signal EN2 for the second clock control circuit 42 according to the signal obtained by inverting the first enable signal EN1.

In some embodiments, the timing constraint causes the data path from the first circuit under test 10 to the second circuit under test 20 to be a false path or a multicycle path but causes the data path from the second circuit under test 20 to the first circuit under test 10 to be a true path.

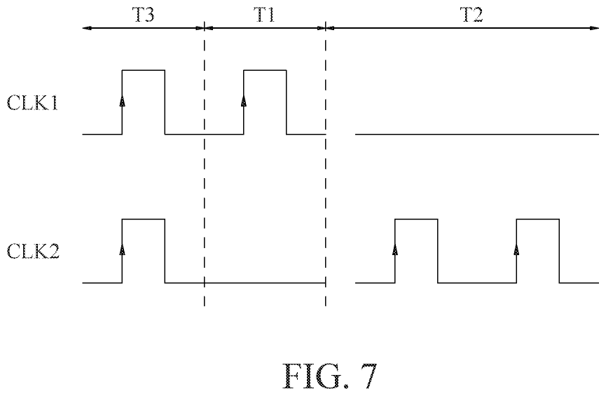

FIG. 7 illustrates schematic waveforms of another embodiment of the first clock signal CLK1 and the second clock signal CLK2. Please refer to FIG. 6 and FIG. 7. During the first operation period T1, the first enable signal ENI enables the first clock control circuit 41 to provide the first clock signal CLK1 for the first circuit under test 10, and the second enable signal EN2 disables the second clock control circuit 42 from providing the second clock signal CLK2 for the second circuit under test 20. During the second operation period T2, the first enable signal EN1 disables the first clock control circuit 41 from providing the first clock signal CLK1 for the first circuit under test 10, and the second enable signal EN2 enables the second clock control circuit 42 to provide the second clock signal CLK2 for the second circuit under test 20. During a third operation period T3, the first enable signal EN1 enables the first clock control circuit 41 to provide the first clock signal CLK1 for the first circuit under test 10, and the second enable signal EN2 enables the second clock control circuit 42 to provide the second clock signal CLK2 for the second circuit under test 20. The first operation period T1, the second operation period T2, and the third operation period do not overlap with each other. In some embodiments, the third operation period T3 is the capture phase of the TDF test for the chip 1.

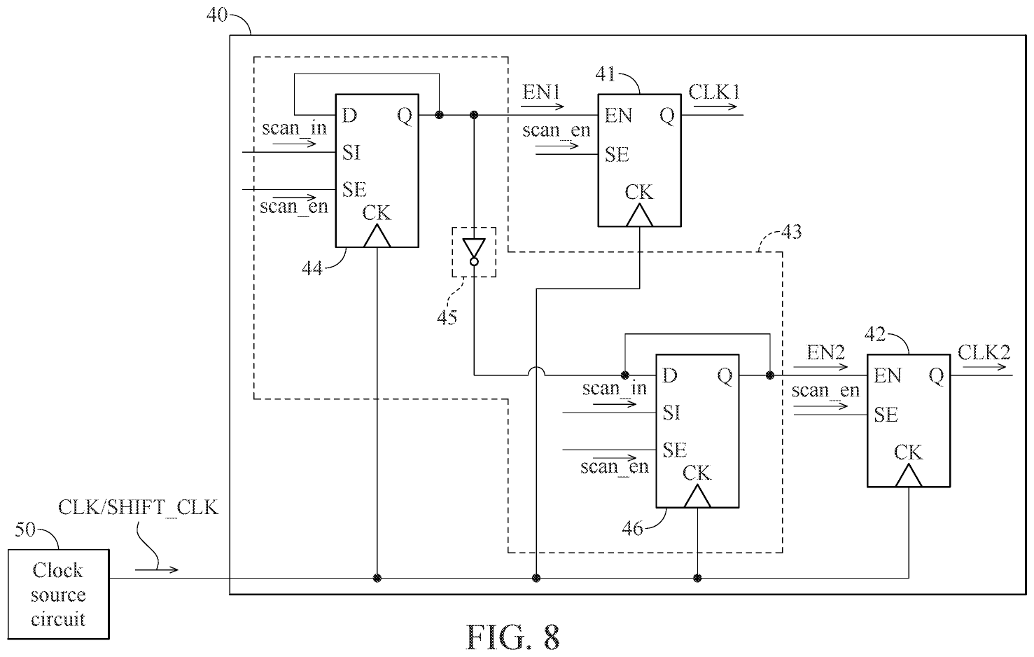

FIG. 8 illustrates a schematic circuit diagram of another embodiment of the clock masking circuit 40. Please refer to FIG. 6 through FIG. 8. In some embodiments, the second enabling unit 46 is a scan flip-flop. The second enabling unit comprises an input end D, an output end Q, a clock end CK, a scan input end SI, and a scan enabling end SE. The input end D is configured to receive the signal obtained by inverting the first enable signal EN1. The output end Q is configured to provide the second enable signal EN2 for the second clock control circuit 42. The clock end CK is configured to receive the initial clock signal CLK and the shift clock signal SHIFT_CLK provided by the clock source circuit 50. The scan input end SI is configured to receive the scan input signal scan_in. The scan enabling end SE is configured to receive the scan enable signal scan_en. The enabling end EN of the second clock control circuit 42 is configured to receive the second enable signal EN2 provided by the second enabling unit 46.

In some embodiments, the first enable signal EN1 is maintained at 1 during the first operation period T1. During the first operation period T1, because the enabling end EN of the first clock control circuit 41 receives the first enable signal EN1 which is provided by the first enabling unit 44 and has the signal value of 1, the first clock control circuit 41 takes the initial clock signal CLK received by the clock end CK of the first clock control circuit 41 as the first clock signal CLK1 and provides the first clock signal CLK1 for the first circuit under test 10. The second enable signal EN2 is maintained at 0 during the first operation period T1. During the first operation period T1, because the enabling end EN of the second clock control circuit 42 receives the second enable signal EN2 which is provided by the second enabling unit 46 and has the signal value of 0, the second clock control circuit 42 does not take the initial clock signal CLK received by the clock end CK of the second clock control circuit 42 as the second clock signal CLK2 and does not provide the second clock signal CLK2 for the second circuit under test 20. In other words, in some embodiments, the second circuit under test 20 will not receive any clock signal during the first operation period T1.

In some embodiments, the first enable signal EN1 is maintained at 0 during the second operation period T2. During the second operation period T2, because the enabling end EN of the first clock control circuit 41 receives the first enable signal EN1 which is provided by the first enabling unit 44 and has the signal value of 0, the first clock control circuit 41 does not take the initial clock signal CLK received by the clock end CK of the first clock control circuit 41 as the first clock signal CLK1 and does not provide the first clock signal CLK1 for the first circuit under test 10. In other words, in some embodiments, the first circuit under test 10 will not receive any clock signal during the second operation period T2. The second enable signal EN2 is maintained at 1 during the second operation period T2. During the second operation period T2, because the enabling end EN of the second clock control circuit 42 receives the second enable signal EN2 which is provided by the second enabling unit 46 and has the signal value of 1, the second clock control circuit 42 takes the initial clock signal CLK received by the clock end CK of the second clock control circuit 42 as the second clock signal CLK2 and provides the second clock signal CLK2 for the second circuit under test 20.

In some embodiments, the first enable signal EN1 is maintained at 1 during the third operation period T3. During the third operation period T3, because the enabling end EN of the first clock control circuit 41 receives the first enable signal EN1 which is provided by the first enabling unit 44 and has the signal value of 1, the first clock control circuit 41 takes the initial clock signal CLK received by the clock end CK of the first clock control circuit 41 as the first clock signal CLK1 and provides the first clock signal CLK1 for the first circuit under test 10. The second enable signal EN2 is also maintained at 1 during the third operation period T3. During the third operation period T3, because the enabling end EN of the second clock control circuit 42 receives the second enable signal EN2 which is provided by the second enabling unit 46 and has the signal value of 1, the second clock control circuit 42 takes the initial clock signal CLK received by the clock end CK of the second clock control circuit 42 as the second clock signal CLK2 and provides the second clock signal CLK2 for the second circuit under test 20.

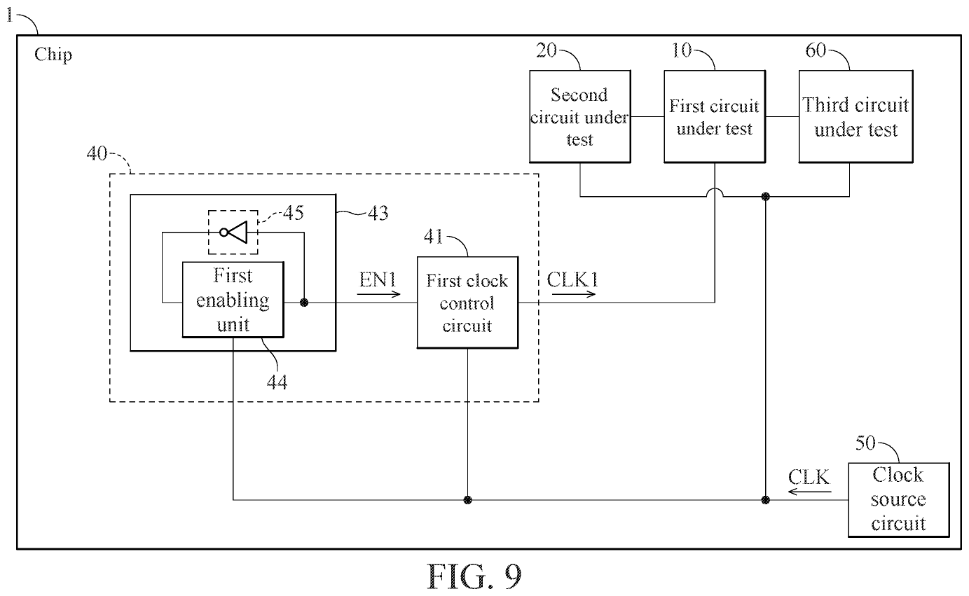

FIG. 9 illustrates a schematic block diagram of yet another embodiment of the chip 1. Please refer to FIG. 9. The chip 1 comprises a first circuit under test 10, a second circuit under test 20, a connection circuit 30, a clock masking circuit 40, and a clock source circuit 50. The second circuit under test 20 is coupled to the input end of the first circuit under test 10 and the clock source circuit 50. The clock masking circuit 40 is coupled to the first circuit under test 10 and the clock source circuit 50.

In some embodiments, the time domain of the first circuit under test 10 and the time domain of the second circuit under test 20 are the same time domain, and the timing constraint causes the data path from the first circuit under test 10 to the second circuit under test 20 and the data path from the second circuit under test 20 to the first circuit under test 10 to both be multicycle paths.

The clock masking circuit 40 comprises the first clock control circuit 41 and an enabling circuit 43. The first clock control circuit 41 is configured to provide the first clock signal CLK1 for the first circuit under test 10 according to the first enable signal EN1 and the initial clock signal CLK. The enabling circuit 43 is configured to provide the first enable signal EN1 for the first clock control circuit 41. The enabling circuit 43 is configured to provide the first enable signal ENI for the first clock control circuit 41. The enabling circuit 43 comprises the first enabling unit 44 and the inverter 45. The first enabling unit 44 is configured to provide the first enable signal EN1 for the first clock control circuit 41. The inverter is coupled to the output end of the first enabling unit 44 and the input end of the first enabling unit 44.

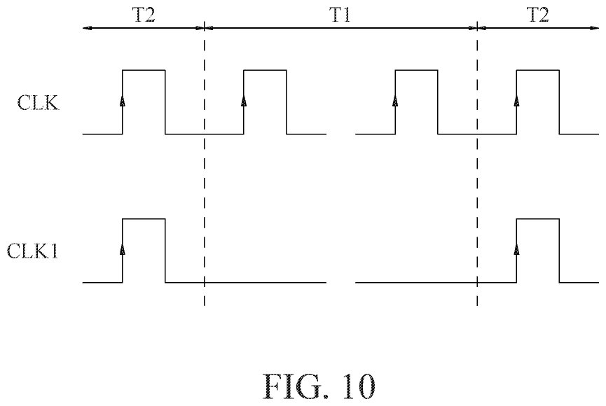

FIG. 10 illustrates schematic waveforms of yet another embodiment of the initial clock signal CLK and the first clock signal CLK1. Please refer to FIG. 9 and FIG. 10. During the first operation period T1, the first enable signal EN1 enables the first clock control circuit 41 to provide the first clock signal CLK1 for the first circuit under test 10, and the clock source circuit 50 provides the initial clock signal CLK for the second circuit under test 20. During the second operation period T2, the first enable signal EN1 disables the first clock control circuit 41 from providing the first clock signal CLK1 for the first circuit under test 10, and the clock source circuit 50 provides the initial clock signal CLK for the second circuit under test 20. The first operation period T1 does not overlap with the second operation period T2.

In some embodiments, the chip 1 further comprises a third circuit under test 60. The third circuit under test 60 is coupled to the output end of the first circuit under test 10. During the first operation period T1 and the second operation period T2, the clock source circuit 50 further provides the initial clock signal CLK for the third circuit under test 60.

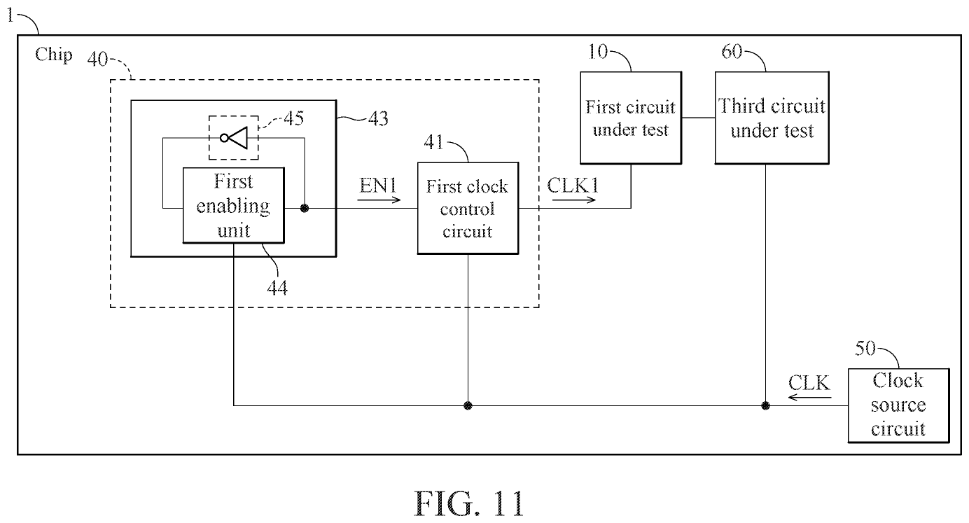

FIG. 11 illustrates a schematic block diagram of a further embodiment of the chip 1. Please refer to FIG. 11. The chip 1 comprises a third circuit under test 60, a clock masking circuit 40, and a clock source circuit 50. The third circuit under test 60 is coupled to the output end of the first circuit under test 10 and the clock source circuit 50. The clock masking circuit 40 is coupled to the first circuit under test 10 and the clock source circuit 50.

The clock masking circuit 40 comprises a first clock control circuit 41 and an enabling circuit 43. The first clock control circuit 41 is configured to provide the first clock signal CLK1 for the first circuit under test 10 according to the first enable signal EN1 and the initial clock signal CLK. The enabling circuit 43 is configured to provide the first enable signal EN1 for the first clock control circuit 41. The enabling circuit 43 comprises the first enabling unit 44 and the inverter 45. The first enabling unit 44 is configured to provide the first enable signal EN1 for the first clock control circuit 41. The inverter 45 is coupled to the output end of the first enabling unit 44 and the input end of the first enabling unit 44.

During the first operation period T1, the first enable signal EN1 enables the first clock control circuit 41 to provide the first clock signal CLK1 for the first circuit under test 10, and the clock source circuit 50 provides the initial clock signal CLK for the third circuit under test 60. During a second operation period T2, the first enable signal EN1 disables the first clock control circuit 41 from providing the first clock signal CLK1 for the first circuit under test 10, and the clock source circuit 50 provides the initial clock signal CLK for the third circuit under test 60. The first operation period T1 does not overlap with the second operation period T2.

As above, in some embodiments, the clock masking circuit 40 can prevent the second circuit under test 20 from capturing the data of the first circuit under test 10 from the first circuit under test 10 or prevent the first circuit under test 10 from capturing the data of the second circuit under test 20 from the second circuit under test 20 during the capture phase. Therefore, the propagation of the unknown signals of the first circuit under test 10 and the second circuit under test 20 can be thus avoided without affecting the abilities of the first circuit under test 10 and the second circuit under test 20 to capture the test responses, so that the test coverage of the chip 1 is increased. Design for gating circuits for masking unknown signals is not necessarily required, and the area cost internal to the chip 1 is reduced.

Although the technical context of the instant disclosure has been disclosed with the preferred embodiments above, the embodiments are not meant to limit the instant disclosure. Any adjustment and retouch done by any person skill in the art without deviating from the spirit of the instant disclosure shall be covered by the scope of the instant disclosure. Therefore, the protected scope of the instant disclosure shall be defined by the attached claims.

What is claimed is:

1. A chip, comprising:
a first circuit under test;
a second circuit under test coupled to the first circuit under test; and
a clock masking circuit comprising;
a first clock control circuit configured to provide a first clock signal for the first circuit under test according to a first enable signal and an initial clock signal;
a second clock control circuit configured to provide a second clock signal for the second circuit under test according to a second enable signal and the initial clock signal; and
an enabling circuit configured to provide the first enable signal for the first clock control circuit and provide the second enable signal for the second clock control circuit;
wherein, during a first operation period, the first enable signal enables the first clock control circuit to provide the first clock signal for the first circuit under test, and the second enable signal disables the second clock control circuit from providing the second clock signal for the second circuit under test; during a second operation period, the first enable signal disables the first clock control circuit from providing the first clock signal for the first circuit under test, and the second enable signal enables the second clock control circuit to provide the second clock signal for the second circuit under test;
wherein, the first operation period does not overlap with the second operation period.

2. The chip according to claim 1, wherein the enabling circuit comprises:
a first enabling unit configured to provide the first enable signal for the first clock control circuit; and
an inverter configured to invert the first enable signal so as to provide the second enable signal for the second clock control circuit.

3. A chip, comprising:
a first circuit under test;
a second circuit under test coupled to the first circuit under test; and
a clock masking circuit comprising:
a first clock control circuit configured to provide a first clock signal for the first circuit under test according to a first enable signal and an initial clock signal;
a second clock control circuit configured to provide a second clock signal for the second circuit under test according to a second enable signal and the initial clock signal; and
an enabling circuit configured to provide the first enable signal for the first clock control circuit and provide the second enable signal for the second clock control circuit;
wherein, during a first operation period, the first enable signal enables the first clock control circuit to provide the first clock signal for the first circuit under test, and the second enable signal disables the second clock control circuit from providing the second clock signal for the second circuit under test; during a second operation period, the first enable signal disables the first clock control circuit from providing the first clock signal for the first circuit under test, and the second enable signal enables the second clock control circuit to provide the second clock signal for the second circuit under test; during a third operation period, the first enable signal enables the first clock control circuit to provide the first clock signal for the first circuit under test, and the second enable signal enables the second clock control circuit to provide the second clock signal for the second circuit under test;
wherein, the first operation period, the second operation period, and the third operation period do not overlap with each other.

4. The chip according to claim 3, wherein the enabling circuit comprises:
a first enabling unit configured to provide the first enable signal for the first clock control circuit;
an inverter configured to invert the first enable signal; and
a second enabling unit configured to provide the second enable signal for the second clock control circuit according to a signal obtained by inverting the first enable signal.

5. The chip according to claim 1, wherein each of the first clock control circuit and the second clock control circuit is a latch.

6. The chip according to claim 3, wherein each of the first clock control circuit and the second clock control circuit is a latch.

7. The chip according to claim 2, wherein the first enabling unit is a scan flip-flop.

8. The chip according to claim 4, wherein the first enabling unit is a scan flip-flop.

9. The chip according to claim 2, wherein the inverter is a PMOS inverter, an NMOS inverter, or a CMOS inverter.

10. The chip according to claim 4, wherein the inverter is a PMOS inverter, an NMOS inverter, or a CMOS inverter.

11. A chip, comprising:
a first circuit under test;
a second circuit under test coupled to an input end of the first circuit under test;
a clock source circuit configured to provide an initial clock signal; and
a clock masking circuit comprising:
a first clock control circuit configured to provide a first clock signal for the first circuit under test according to a first enable signal and the initial clock signal; and
an enabling circuit configured to provide the first enable signal for the first clock control circuit;
wherein, during a first operation period, the first enable signal enables the first clock control circuit to provide the first clock signal for the first circuit under test, and the clock source circuit provides the initial clock signal for the second circuit under test; during a second operation period, the first enable signal disables the first clock control circuit from providing the first clock signal for the first circuit under test, and the clock source circuit provides the initial clock signal for the second circuit under test;
wherein the first operation period does not overlap with the second operation period.

12. The chip according to claim 11, further comprising:
a third circuit under test coupled to an output end of the first circuit under test;
wherein, during the first operation period and the second operation period, the clock source circuit further provides the initial clock signal for the third circuit under test.
